(19) United States
(12) Patent Application Publication
(10) Pub. No.: US 2021/0083015 A1
(43) Pub. Date: Mar. 18, 2021

(54) DISPLAY DEVICE AND PIXEL STRUCTURE THEREOF

(71) Applicant: Wuhan China Star Optoelectronics Technology Co.,Ltd, Wuhan, Hubei (CN)

(72) Inventor: Yuebai HAN, Wuhan, Hubei (CN)

(21) Appl. No.: 16/069,294

(22) PCT Filed: Apr. 2, 2018
(86) PCT No.: PCT/CN2018/081591

§ 371 Date: Jul. 11, 2018

(30) Foreign Application Priority Data
Mar. 20, 2018 (CN) 201810229451.0

(51) Int. Cl. H01L 27/32

(52) U.S. Cl. CPC H01L 27/3218

(57) ABSTRACT

Provided are a display device and a pixel structure thereof. The pixel structure comprises a plurality of pixel units arranged in an array, wherein each of the pixel units comprises three sub pixels, and the three sub pixels are respectively used to display three colors of red, green and blue, and each of the sub pixels comprises a bent portion, and bent portions of sub pixels on a same row have a same bent direction. In the provided pixel structure, each sub pixel includes a bent portion. The bent portions of the sub pixels on the same row are the same bent direction. Since the sub pixels include bent portions, the color distribution of the pixel structure in different directions can be made more uniform, thereby improving light transmittance and color gamut to promote display result.

### FIELD OF THE INVENTION

The present invention relates to a curved display field, and more particularly to a display device and a pixel structure thereof.

### BACKGROUND OF THE INVENTION

With the development of science and technology, more and more interaction occurs between humans and devices, and the display panel is becoming more and more important as an interface between humans and devices. How to obtain a panel possessing high light transmittance, low power consumption, high color gamut and high resolution rate has become the point of engineers of all major panel manufacturers who are constantly pursuing research.

### SUMMARY OF THE INVENTION

For solving the aforesaid problem, the present invention provides a display device and a pixel structure thereof, which can improve light transmittance and color gamut to promote display result.

An objective of the present invention is to provide a pixel structure, comprising a plurality of pixel units arranged in an array, wherein each of the pixel units comprises three sub pixels, and the three sub pixels are respectively used to display three colors of red, green and blue, and each of the sub pixels comprises a bent portion, and bent portions of sub pixels on a same row have a same bent direction.

Optionally, the bent portions of the sub pixels on an odd row are bent in a first direction, and the bent portions of the sub pixels on an even row are bent in a second direction, and the first direction is opposite to the second direction.

Optionally, the bent portions are in a fold line shape.

Optionally, the bent portions are in a curved shape.

Optionally, arrangements of the three sub pixels in the pixel unit on the odd row are the same, and arrangements of the three sub pixels in the pixel unit on the even row are the same.

Optionally, the arrangements of the three sub pixels in the pixel unit on the odd row are different from the arrangements of the three sub pixels in the pixel unit on the even row.

Optionally, any two adjacent sub pixels display different colors.

Optionally, the sub pixels on the odd row are aligned with the sub pixels on the even row.

Optionally, the sub pixels on the odd row are offset from the sub pixels on the even row.

The present invention further provides a display device. The display device comprises any one of the aforesaid pixel structures.

In the provided pixel structure, each sub pixel includes a bent portion. The bent portions of the sub pixels on the same row are the same bent direction. Since the sub pixels include bent portions, the color distribution of the pixel structure in different directions can be made more uniform, thereby improving light transmittance and color gamut to promote display result.

### BRIEF DESCRIPTION OF THE DRAWINGS

FIG. 1 is a structure diagram of a pixel structure;

FIG. 2 is another structure diagram of a pixel structure;

FIG. 3 is one another structure diagram of a pixel structure.

### DETAILED DESCRIPTION OF PREFERRED EMBODIMENTS

Hereinafter, the embodiments of the present invention will be described in detail with reference to the accompanying drawings. However, the present invention may be embodied in various different forms and should not be construed as limited to the specific embodiments set forth herein. Rather, these embodiments are provided to explain the principles of the present invention and the practical application thereof to thereby enable those of ordinary skill in the art to understand the various embodiments of the present invention and the various adaptations for the specific intended application. In the drawings, the same reference numerals will be used to refer to the same elements throughout.

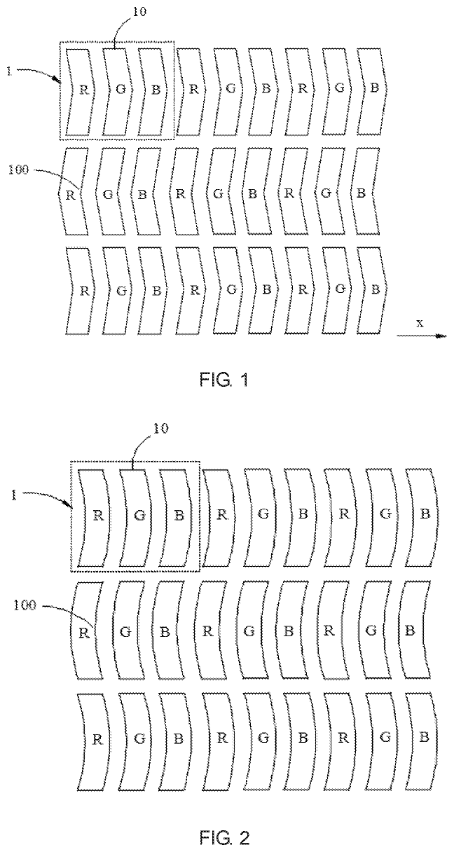

Please refer to FIG. 1. The pixel structure provided by the embodiment comprises a plurality of pixel units 1 arranged in an array, wherein each of the pixel units 1 comprises three sub pixels 10, and the three sub pixels are respectively used to display three colors of red (R), green (G) and blue (B), and each of the sub pixels 10 comprises a bent portion 100, and bent portions 100 of sub pixels 10 on a same row have a same bent direction.

Each row of the pixel structure comprises at least one pixel unit 1, and the bent directions of the bent portions 100 of the sub pixels 10 on different rows may be the same or different. Preferably, the bent portions 100 of the sub pixels 10 on an odd row have the same bent direction, and the bent portions 100 of the sub pixels 10 on an even row have the same bent direction, and the bent direction of the bent portions 100 of the sub pixels 10 on the odd row is different from the bent direction of the bent portions 100 of the sub pixels 10 on the even row.

Specifically, the bent portions 100 of the sub pixels 10 on the odd row are bent in a first direction, and the bent portions 100 of the sub pixels 10 on the even row are bent in a second direction, and the first direction is opposite to the second direction. Here, it means that the bent portions 100 of the sub pixels 10 on the odd row are bent toward the right, and the bent portions 100 of the sub pixels 10 on the even row are bent toward the left.

The sub pixels 10 comprise the bent portions 100. Thus, the color distribution of the pixel structure in different directions can be made more uniform. Besides, by arranging the bent directions of the bent portions 100 of the sub pixels 10 on different rows to be different, the color distribution of the pixel structure in different directions can be made more uniform in advance.

The bent portions 100 can be in a fold line shape. As shown in FIG. 1, the bent portion 100 is in a bi-folded line shape and includes two folded sides and two parallel sides. The folded sides on the odd row are bent toward the right, and the folded sides on the even row are bent toward the left. The bent points of the folded sides on the same row are located on the same straight line.

The sub pixels 10 on the odd row are aligned with the sub pixels 10 on the even row. Namely, for the same column, the parallel sides of the sub pixel 10 located on different rows are aligned with each other. For the same column, a projection of the two parallel sides of the sub pixel 10 on the odd row are coincident with a projection the two parallel sides of the sub pixel 10 on the even row in the x-axis. For the same column, a projection of the bent point of the two folded sides of the sub pixel 10 on the odd row and a projection of the bent point of the two folded sides of the sub pixel 10 on the even row are symmetrical about a central axis of the sub pixels 10 on the column.

The arrangements of the three sub pixels 10 in the pixel unit 1 on the odd row are the same, and the arrangements of the three sub pixels 10 in the pixel unit 1 on the even row are the same. The arrangements of the three sub pixels 10 in the pixel unit 1 on the odd row are the same as the arrangements of the three sub pixels 10 in the pixel unit 1 on the even row. As shown in FIG. 1, the first row and the second row are illustrated. Starting from the left of the first row, the sub pixels 10 in each pixel unit 1 are respectively used to display three colors of R, G and B. Similarly, starting from the left of the second row, the sub pixels 10 in each pixel unit 1 are respectively used to display three colors of R, G and B.

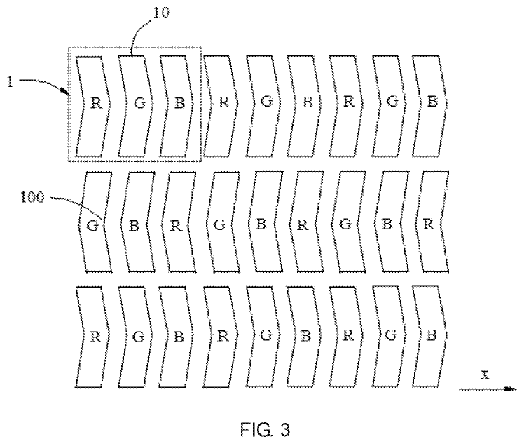

Please refer to FIG. 2. The bent portions 100 can also be in a curved shape. The sub pixel 10 is in a bi-curved shape, and includes two curves and two parallel sides. The curves on the odd row are bent toward the right, and the curves on the even row are bent toward the left. The centers of the circles where the curves are on the same row are located on the same straight line.

For the same column, the parallel sides of the sub pixel 10 located on different rows are aligned with each other. Namely, for the same column, a projection of the two parallel sides of the sub pixel 10 on the odd row are coincident with a projection the two parallel sides of the sub pixel 10 on the even row in the x-axis. For the same column, a projection of the center of the circles where the two curves are of the sub pixel 10 on the odd row and a projection of the centers of the circles where the two curves are of the sub pixel 10 on the even row are symmetrical about a central axis of the sub pixels 10 on the column.

Please refer to FIG. 3. In another embodiment, the sub pixels 10 on the odd row can also be offset from the sub pixels 10 on the even row. Namely, for the same column, projections of the parallel sides of the sub pixels 10 on the different rows in the x-axis are offset with a certain distance. Here, the offset distance can be adjusted according to actual needs. By offsetting the sub pixels 10 on the odd row from the sub pixels 10 on the even row, the color distribution of the pixel structure in different directions can be made more uniform in advance.

Besides, in this embodiment, the arrangements of the three sub pixels 10 in the pixel unit 1 on the odd row are the same, and the arrangements of the three sub pixels 10 in the pixel unit 1 on the even row are the same. The arrangements of the three sub pixels 10 in the pixel unit 1 on the odd row are different from the arrangements of the three sub pixels 10 in the pixel unit 1 on the even row. The first row and the second row are illustrated. Starting from the left of the first row, the sub pixels 10 in each pixel unit 1 are respectively used to display three colors of R, G and B. Similarly, starting from the left of the second row, the sub pixels 10 in each pixel unit 1 are respectively used to display three colors of B, G R, or B, R, G, or G, B, R, or G, R, B.

Preferably, in order to make the color distribution of the entire pixel structure more uniform, any two adjacent sub pixels display different colors. The first row and the second row are illustrated. Starting from the left of the first row, the sub pixels 10 in each pixel unit 1 are respectively used to display three colors of R, G and B. Starting from the left of the second row, the sub pixels 10 in each pixel unit 1 are respectively used to display three colors of G, B and R (as shown in FIG. 3) or B, R and G.

In this embodiment, the pixel unit 1 can also comprise three sub pixels 10 on different rows. As an illustration shown in FIG. 3, one pixel unit 1 can comprise the first sub pixel of the first row, and the first sub pixel and the second sub pixel of the second row. The first sub pixel of the first row is used to display the color of red R. The first sub pixel and the second sub pixel of the second row are respectively used to display the colors of green G and blue B. Another pixel unit 1 can comprise the second sub pixel and the third sub pixel of the first row, and the third sub pixel of the second row. The second sub pixel and the third sub pixel of the first row are respectively used to display the colors of green G and blue B. The third sub pixel of the second row is used to display the color of red R. Of course, this is merely shown as an illustration, and the pixel unit 1 may be configured by selecting other arrangements or combinations according to actual needs.

The display device in this embodiment may be an LCD or an OLED. Other structures of the display device except the pixel structure are the same as those of the existing display device, and the description will not be repeated here.

Above are only specific embodiments of the present application, the scope of the present application is not limited to this, and to any persons who are skilled in the art, change or replacement which is easily derived should be covered by the protected scope of the application. Thus, the protected scope of the application should go by the subject claims.

What is claimed is:

1. A pixel structure, comprising a plurality of pixel units arranged in an array, wherein each of the pixel units comprises three sub pixels, and the three sub pixels are respectively used to display three colors of red, green and blue, and each of the sub pixels comprises a bent portion, and bent portions of sub pixels on a same row have a same bent direction.

2. The pixel structure according to claim 1, wherein the bent portions of the sub pixels on an odd row are bent in a first direction, and the bent portions of the sub pixels on an even row are bent in a second direction, and the first direction is opposite to the second direction.

3. The pixel structure according to claim 2, wherein the bent portions are in a fold line shape.

4. The pixel structure according to claim 2, wherein the bent portions are in a curved shape.

5. The pixel structure according to claim 1, wherein arrangements of the three sub pixels in the pixel unit on the odd row are the same, and arrangements of the three sub pixels in the pixel unit on the even row are the same.

6. The pixel structure according to claim 5, wherein the arrangements of the three sub pixels in the pixel unit on the odd row are different from the arrangements of the three sub pixels in the pixel unit on the even row.

7. The pixel structure according to claim 6, wherein any two adjacent sub pixels display different colors.

8. The pixel structure according to claim 1, wherein the sub pixels on the odd row are aligned with the sub pixels on the even row.

9. The pixel structure according to claim 2, wherein the sub pixels on the odd row are aligned with the sub pixels on the even row.

10. The pixel structure according to claim 5, wherein the sub pixels on the odd row are aligned with the sub pixels on the even row.

11. The pixel structure according to claim 1, wherein the sub pixels on the odd row are offset from the sub pixels on the even row.

12. The pixel structure according to claim 2, wherein the sub pixels on the odd row are offset from the sub pixels on the even row.

13. The pixel structure according to claim 5, wherein the sub pixels on the odd row are offset from the sub pixels on the even row.

14. A display device, comprising a pixel structure, wherein the pixel structure comprises a plurality of pixel units arranged in an array, and each of the pixel units comprises three sub pixels, and the three sub pixels are respectively used to display three colors of red, green and blue, and each of the sub pixels comprises a bent portion, and bent portions of sub pixels on a same row have a same bent direction.

15. The display device according to claim 14, wherein the bent portions of the sub pixels on an odd row are bent in a first direction, and the bent portions of the sub pixels on an even row are bent in a second direction, and the first direction is opposite to the second direction.

16. The display device according to claim 15, wherein the bent portions are in a fold line shape.

17. The display device according to claim 14, wherein arrangements of the three sub pixels in the pixel unit on the odd row are the same, and arrangements of the three sub pixels in the pixel unit on the even row are the same.

18. The display device according to claim 17, wherein the arrangements of the three sub pixels in the pixel unit on the odd row are different from the arrangements of the three sub pixels in the pixel unit on the even row.

19. The display device according to claim 14, wherein the sub pixels on the odd row are aligned with the sub pixels on the even row.

20. The display device according to claim 14, wherein the sub pixels on the odd row are offset from the sub pixels on the even row.
